(19) United States
(12) Patent Application Publication
(10) Pub. No.: US 2025/0379155 A1
(43) Pub. Date: Dec. 11, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: Seunggeol RYU, Suwon-si (KR); Seungsoo HA, Suwon-si (KR)

(73) Assignee: Samsung Electronics Co., Ltd., Suwon-si (KR)

(21) Appl. No.: 19/024,346

(22) Filed: Jan. 16, 2025

(30) Foreign Application Priority Data
Jun. 5, 2024 (KR) 10-2024-0073440

(51) Int. Cl. H01L 23/538; H01L 21/48; H01L 23/373; H01L 25/00; H01L 25/16

(52) U.S. Cl. CPC H01L 23/5389; H01L 21/4846; H01L 21/4882; H01L 23/3735; H01L 23/5385; H01L 25/16; H01L 25/50

(57) ABSTRACT

A semiconductor package includes a first package including at least two semiconductor chips, a second package including at least one semiconductor chip and disposed on an upper side of the first package, and a heat dissipation device disposed on the upper side of the first package. The heat dissipation device may be disposed on an upper side of a first region of the first package to which a (1-1)-th semiconductor chip is mounted, and the second package may be disposed on an upper side of a second region of the first package to which a (1-2)-th semiconductor chip is mounted. A cavity that is exposed to the heat dissipation device may be defined in the first region of the first package, and the (1-1)-th semiconductor chip may be disposed in the cavity. The (1-2)-th semiconductor chip may be embedded in the second region of the first package.

### CROSS-REFERENCE TO RELATED APPLICATION

This application claims priority under 35 U.S.C. § 119 to Korean Patent Application No. 10-2024-0073440 filed on Jun. 5, 2024, in the Korean Intellectual Property Office, the entire disclosure of which is incorporated herein by reference.

### BACKGROUND

Example embodiments relate to semiconductor packages including a plurality of semiconductor chips and methods of manufacturing the semiconductor packages.

Due to advancements in technology, materials, and/or manufacturing processes, computing power and wireless communication technology have improved. As a result, integration of higher-performance transistors can be increased or improved. Electronic systems can be made lighter, thinner, and/or more portable, and power efficiency thereof can be increased using system packaging, which implements a system within a package.

System packaging reduces or minimizes form factor and/or improves reliability, lowers power consumption, and/or lowers manufacturing costs. Due to higher integration, heat generated in semiconductor packages may increase and it may be advantageous to more efficiently dissipate the heat.

### SUMMARY

Some example embodiments are directed to semiconductor packages having improved heat dissipation resulting in an improved or higher reliability, and methods of manufacturing the semiconductor packages.

According to some example embodiments, a semiconductor package may include a first package including at least two semiconductor chips, a second package including at least one semiconductor chip and on an upper side of the first package, and a heat dissipation device on the upper side of the first package. The heat dissipation device is on an upper side in a first region of the first package to which a (1-1)-th semiconductor chip is mounted, the second package is on an upper side of a second region of the first package to which a (1-2)-th semiconductor chip is mounted. A cavity that is exposed to the heat dissipation device may be defined in the first region of the first package, and the (1-1)-th semiconductor chip may be in the cavity. The (1-2)-th semiconductor chip may be in the second region of the first package.

Alternatively or additionally, according to some example embodiments, a method of manufacturing a semiconductor package may include forming a first package including a (1-1)-th semiconductor chip and a (1-2)-th semiconductor chip, disposing a heat dissipation device on an upper side in a first region of the first package to which the (1-1)-th semiconductor chip is mounted, and disposing a second package including at least one semiconductor chip on an upper side in a second region of the first package to which the (1-2)-th semiconductor chip is mounted. Forming the first package may include embedding the (1-2)-th semiconductor chip in the second region of the first package, and forming, in the first region of the first package, a cavity that is open toward an upper side of the first package and disposing the (1-1)-th semiconductor chip in the cavity.

A semiconductor package and a method of manufacturing the semiconductor package, according to some example embodiments, may reduce thermal coupling between semiconductor chips by improving and/or increasing the cooling efficiency of a semiconductor chip mounted in a first package.

Additionally or alternatively, the semiconductor package and the method of manufacturing the semiconductor package, according to some example embodiments, may implement a package on package (PoP) configuration having lower manufacturing costs and/or turnaround time (TAT) by omitting an additional interposer or redistributed layer (RDL) that may be disposed between the first package and a second package when the second package is stacked on the upper side of the first package.

Additionally or alternatively, the semiconductor package and the method of manufacturing the semiconductor package, according to some example embodiments, may improve thermal characteristics by increasing and/or maximizing cooling of a semiconductor chip included in the semiconductor package. Furthermore, by efficiently packaging a plurality of semiconductor chips, the overall system resistance or impedance may be reduced, and operating speeds may be increased, and as a result, electrical characteristics of the semiconductor package including the semiconductor chip may be improved.

The technical effects achieved by some example embodiments of the present disclosure are not limited to those described above, and other technical effects not mentioned above will be clearly derived and understood by one of ordinary skill in the art from the following description.

### BRIEF DESCRIPTION OF THE DRAWINGS

Example embodiments will be more clearly understood from the following detailed description taken in conjunction with the accompanying drawings in which:

FIG. 1 is a plan view of a semiconductor package, according to some example embodiments.

FIG. 2 is a cross-sectional view taken along a line I-I′ of FIG. 1.

FIG. 3 is an enlarged view of a portion “X” of FIG. 2.

FIG. 4 illustrates a redistributed layer (RDL) disposed between a first package and a second package of FIGS. 2 and 3.

FIG. 5 is an enlarged view of a portion “Y” of FIG. 2.

FIG. 6 is an enlarged view of a portion “Y” of FIG. 2, according to some example embodiments.

FIG. 7 is a plan view illustrating a semiconductor package, according to some example embodiments.

FIG. 8 is a cross-sectional view taken along a line I-I′ of FIG. 7.

FIG. 9 is a plan view illustrating a semiconductor package, according to some example embodiments.

FIG. 10 is a cross-sectional view taken along a line I-I′ of FIG. 9.

FIG. 11 is a plan view illustrating a semiconductor package, according to some example embodiments.

FIG. 12 is a cross-sectional view taken along a line I-I′ of FIG. 11.

FIG. 13 is a plan view illustrating a semiconductor package, according to some example embodiments.

FIG. 14 is a cross-sectional view taken along a line I-I′ of FIG. 13.

FIG. 15 is a plan view illustrating a semiconductor package, according to some example embodiments.

FIG. 16 is a cross-sectional view taken along a line I-I′ of FIG. 15.

FIGS. 17, 18, and 19 are cross-sectional views illustrating the second package or the third package of a semiconductor package, according to some example embodiments.

FIG. 20 is a flowchart of a method of manufacturing a semiconductor package, according to some example embodiments.

FIGS. 21, 22, 23, 24, 25, and 26 illustrate a process of manufacturing a semiconductor package, according to some example embodiments.

FIG. 27 illustrates a configuration of an electronic device system including a semiconductor package, according to some example embodiments.

### DETAILED DESCRIPTION

Hereinafter, example embodiments will be described in detail with reference to the accompanying drawings. However, various alterations and modifications may be made to the example embodiments. Here, the example embodiments are not intended to be limited by the descriptions of the present disclosure. The example embodiments should be understood to include all changes, equivalents, and replacements within the idea and the technical scope of the disclosure.

The terminology used herein is for the purpose of describing particular embodiments only and is not intended to be limiting. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, components, or a combination thereof, but do not preclude the presence or addition of one or more other features, integers, steps, operations, elements, components or groups thereof.

Unless otherwise defined, all terms used herein including technical or scientific terms have the same meaning as commonly understood by one of ordinary skill in the art to which this disclosure pertains. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a description related thereto is not repeated.

In addition, terms such as first, second, A, B, (a), (b), and the like may be used to describe components of the embodiments. These terms are used only for the purpose of discriminating one component from another component, and the nature, the sequences, or the orders of the components are not limited by the terms. When one component is described as being “connected”, “coupled”, or “attached” to another component, it should be understood that one component may be connected or attached directly to another component, and an intervening component may also be “connected”, “coupled”, or “attached” to the components.

The same name may be used to describe an element included in the embodiments described above and an element having a common function. Unless otherwise mentioned, the description on an embodiment may be applicable to other embodiments and thus, duplicated descriptions will be omitted for conciseness.

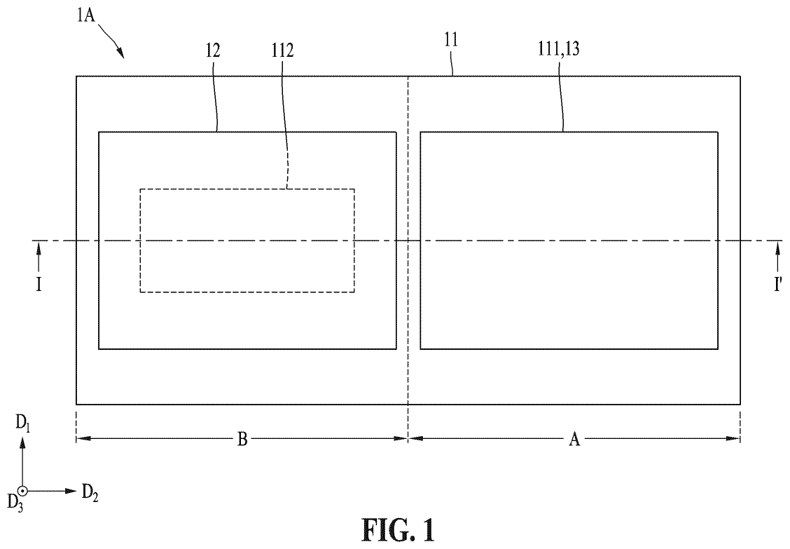

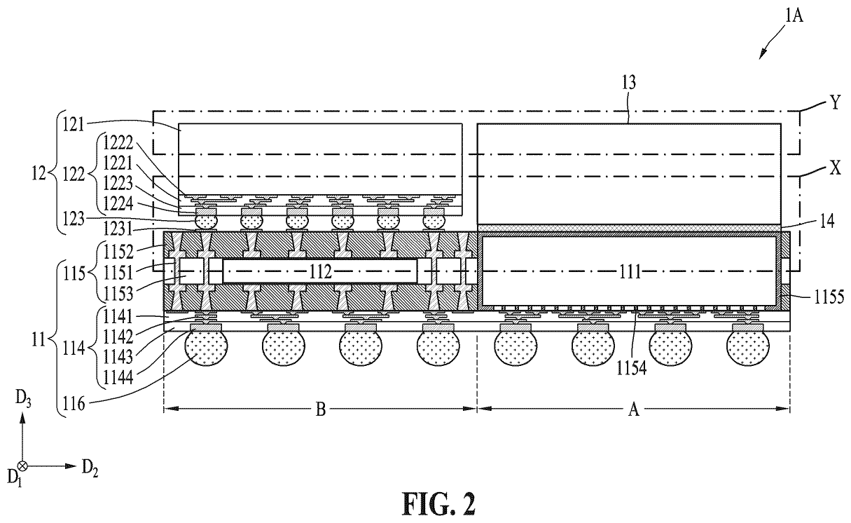

FIG. 1 is a plan view illustrating a semiconductor package according to some example embodiments. FIG. 2 is a cross-sectional view taken along a line I-I′ of FIG. 1.

Referring to FIGS. 1 and 2, a semiconductor package 1A, according to some example embodiments, may include a first package 11, a second package 12, and a heat dissipation device 13. The first package 11 may include at least two semiconductor chips. The second package 12 may include at least one semiconductor chip and may be disposed on the upper side of the first package 11. The heat dissipation device 13 may be disposed on the upper side of the first package 11. The second package 12 and the heat dissipation device 13 may be spaced apart from each other on the upper side of the first package 11.

The first package 11 of the semiconductor package 1A may include a (1-1)-th semiconductor chip 111 and a (1-2)-th semiconductor chip 112, each performing different functions. The (1-1)-th semiconductor chip 111 and the (1-2)-th semiconductor chip 112 may be disposed side by side in a first direction D₁ and a second direction D₂. Although FIGS. 1 and 2 illustrate one (1-1)-th semiconductor chip 111 and one (1-2)-th semiconductor chip 112, example embodiments are not limited thereto. In some example embodiments, the first package 11 may include more than two semiconductor chips.

For reference, the first direction D₁ and the second direction D₂ may be parallel to the bottom surface of the first package 11 and perpendicular to each other. A third direction D₃ may be perpendicular to the first direction D₁ and the second direction D₂.

The (1-1)-th semiconductor chip 111 may include a logic chip. A plurality of logic elements may be included in the logic chip. A logic element may be, for example, an element for performing various kinds of signal processing including a logic circuit such as an AND, an OR, a NOT, a flip flop, and the like. In some example embodiments, a logic element may be an element for performing signal processing such as analog signal processing, analog-to-digital (A/D) conversion, control, and the like.

In some example embodiments, the (1-1)-th semiconductor chip 111 may be implemented as a microprocessor, a graphics processor, a signal processor, a network processor, a chipset, an application processor, a system-on-chip (SoC), an application-specific integrated circuit (ASIC), or the like, depending on the functions and/or applications.

The (1-2)-th semiconductor chip 112 may include a volatile memory chip and/or a non-volatile memory chip. The volatile memory chip may be, for example, dynamic random access memory (DRAM), static RAM (SRAM), or thyristor RAM (TRAM). The non-volatile memory chip may be, for example, flash memory, magnetic RAM (MRAM), spin transfer torque MRAM (STT-MRAM), ferroelectric RAM (FRAM), phase change RAM (PRAM), or resistive RAM (RRAM), a combination thereof, and the like.

In some example embodiments, the (1-2)-th semiconductor chip 112 may include a memory chiplet including a plurality of memory chips configured to exchange or communicate data with each other. In some example embodiments, the (1-2)-th semiconductor chip 112 may include a high bandwidth memory (HBM) chip.

The first package 11 may include a first redistributed layer (RDL) 114, a first package substrate 115 disposed on one (or upper) surface of the first RDL 114 and accommodating the (1-1)-th semiconductor chip 111 and the (1-2)-th semiconductor chip 112, and a first connecting terminal 116 disposed on the other (or lower) surface of the first RDL 114.

The first package substrate 115 may include a first wiring pattern 1151, a first insulating layer 1152, a first core layer 1153, a first pad 1154, and a molding 1155. The (1-2)-th semiconductor chip 112 may be disposed in the first core layer 1153. The (1-2)-th semiconductor chip 112 may be embedded in a second region B of the first package 11. The (1-2)-th semiconductor chip 112 may be encapsulated within the first package 11 and none of the surfaces of the (1-2)-th semiconductor chip 112 are exposed. A cavity (discussed below) that is open toward (or exposed to) the heat dissipation device 13 may be formed in (or otherwise defined by) a first region A of the first package 11. The (1-1)-th semiconductor chip 111 may be disposed or positioned in the cavity. The upper surface of the (1-1)-th semiconductor chip 111 may not be encapsulated in or otherwise covered by the first package 11. The upper surface of the (1-1)-th semiconductor chip 111 may be exposed to the heat dissipation device 13 in the first region A of the first package 11. The term “region,” as used herein, may refer to a three-dimensional space (or volume) defined by the first direction D₁ the second direction D₂, and the third direction D₃.

The first wiring pattern 1151 may be formed in the first package substrate 115 and may be electrically connected to the (1-2)-th semiconductor chip 112. The first pad 1154 may be formed in the first package substrate 115 and may be electrically connected to the (1-1)-th semiconductor chip 111. The molding 1155 may surround the periphery of the (1-1)-th semiconductor chip 111. The first insulating layer 1152 may fill (or occupy) the inside or interior of the first package substrate 115, and may form the first package substrate 115 at least in part.

For the (1-1)-th semiconductor chip 111, the first pad 1154 may be formed on (e.g., only on) the lower side of the (1-1)-th semiconductor chip 111, and electrical connections may be absent on the upper side of the (1-1)-th semiconductor chip 111. The lower surface of the (1-1)-th semiconductor chip 111 may be connected to the first pad 1154.

The first pad 1154 may be formed as a bump, but example embodiments are not limited thereto and the first pad 1154 may have other shapes. The first pad 1154 may be formed of or may include a conductive material, such as copper. However, example embodiments are not limited thereto, and the first pad 1154 may be formed of or may include other conductive materials. The length of the first pad 1154 may be 3 micrometers (μm) or about 3 μm, but in some example embodiments the length may be more than 3 μm or about 3 μm, or the length may be less than 3 μm (or about 3 μm), depending on application and/or design.

For the (1-2)-th semiconductor chip 112, the first wiring pattern 1151 may be formed on both the upper and lower sides of the (1-2)-th semiconductor chip 112. Both the upper and lower surfaces of the (1-2)-th semiconductor chip 112 may be connected to the first wiring pattern 1151.

The first wiring pattern 1151 may be formed of or may include nickel (Ni), copper (Cu), palladium (Pd), platinum (Pt), gold (Au), or a combination thereof, and the first insulating layer 1152 of the first package substrate 115 may be formed of or may include an epoxy-based resin, a phenolic resin, or the like.

The molding 1155 may be formed of or may include an insulating material. The material of the molding 1155 may be the same as or different from a material of the first insulating layer 1152.

The first pad 1154 disposed on the lower surface of the (1-1)-th semiconductor chip 111 may electrically connect the (1-1)-th semiconductor chip 111 to the first RDL 114. The first wiring pattern 1151 disposed on the lower surface of the (1-2)-th semiconductor chip 112 may electrically connect the (1-2)-th semiconductor chip 112 to the first RDL 114. The (1-1)-th semiconductor chip 111 and the (1-2)-th semiconductor chip 112 may be electrically connected to each other through the first pad 1154, the first wiring pattern 1151, and the first RDL 114.

The first RDL 114 may include a plurality of redistributed patterns, a bump pattern, and a redistributed insulating layer. In some example embodiments, the first RDL 114 may include a plurality of redistributed insulating layers that may be stacked. The redistributed insulating layer may be formed from or using, for example, photo imageable dielectric (PID) and/or photosensitive polyimide (PSPI). The redistributed pattern and the bump pattern may be or include, for example, a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and the like or alloys thereof. However, in some example embodiments the redistributed pattern and the bump pattern may be or include other conductive materials. In some example embodiments, the redistributed pattern and the bump pattern may be formed by stacking metals or metal alloys on a seed layer including titanium, titanium nitride, and/or titanium tungsten.

For example, the first RDL 114 may include a (1-1)-th redistributed insulating layer 1141, a (1-2)-th redistributed insulating layer 1143 disposed on the lower side of the (1-1)-th redistributed insulating layer 1141, a plurality of first redistributed patterns 1142 disposed in the (1-1)-th redistributed insulating layer 1141, and a first bump pattern 1144 disposed in the (1-2)-th redistributed insulating layer 1143.

The first bump pattern 1144 may be disposed on the lowermost side of the first RDL 114. The lower surface of the first bump pattern 1144 may be exposed to the (1-2)-th redistributed insulating layer 1143. The first bump pattern 1144 may function as pads of the first connecting terminal 116 to be described below. A plurality of first bump patterns 1144 may be spaced apart from each other and may be electrically insulated from each other. The plurality of first bump patterns 1144 may be spaced apart from each other in the second direction D₂ parallel to the lower surface of the first RDL 114.

The first redistributed pattern 1142 may be disposed on the first bump pattern 1144. The first redistributed pattern 1142 may be electrically connected to the first bump pattern 1144. A plurality of first redistributed patterns 1142 may be disposed along a same line (or in a straight line) in the second direction D₂, may be spaced apart and electrically insulated from one another. Some of the plurality of first redistributed patterns 1142, which extend different lengths or distances in the third direction D₃, may be electrically connected to one another.

The first redistributed pattern 1142 may include a first via portion and a first wiring portion. The first via portion may be a component for a vertical connection and the first wiring portion may be a component for a horizontal connection. The first via portion may be a portion of the first redistributed pattern 1142 extending in the third direction D₃ and the first wiring portion may be a portion of the first redistributed pattern 1142 extending in the second direction D₂. The width of the first wiring portion may be greater than the width of the first via portion.

The semiconductor package 1A may be electrically connected to another semiconductor package, a package board, or the like via the first connecting terminal 116. FIG. 2 illustrates the first connecting terminal 116 is illustrated as ball shaped. However, example embodiments are not limited thereto, and in some example embodiments, the first connecting terminal 116 may be shaped as or may be, for example, a bump, a grid array, a conductive tab, or the like. A plurality of first connecting terminals 116 may be formed on the lower surface of the first RDL 114.

The (1-2)-th semiconductor chip 112 may be mounted on (or supported by) the second package 12 that may be disposed on the upper side of the first package 11 in the second region B. The second package 12 may include a second package substrate 121, a second RDL 122, and a second connecting terminal 123. The second package substrate 121 may include at least one second semiconductor chip and a second insulating layer filling (or occupying) the inside (or interior) of the second package substrate 121, and at least in part forming the second package 12. The second package substrate 121 may be disposed on one (or upper) surface of the second RDL 122. The second connecting terminal 123 may be disposed on the other (or lower) surface of the second RDL 122. A second pad 1231 may be disposed on the lower side of the second connecting terminal 123. The second connecting terminal 123 may be electrically connected to the first wiring pattern 1151 of the first package 11 via the second pad 1231.

For example, the second RDL 122 may include a (2-1)-th redistributed insulating layer 1221, a (2-2)-th redistributed insulating layer 1223 disposed on the lower side of the (2-1)-th redistributed insulating layer 1221, a plurality of second redistributed patterns 1222 disposed in the (2-1)-th redistributed insulating layer 1221, and a second bump pattern 1224 disposed in the (2-2)-th redistributed insulating layer 1223.

The (2-1)-th redistributed insulating layer 1221, the (2-2)-th redistributed insulating layer 1223, the second redistributed pattern 1222, and the second bump pattern 1224 may be similar in some respects to the (1-1)-th redistributed insulating layer 1141, the (1-2)-th redistributed insulating layer 1143, the first redistributed pattern 1142, and the first bump pattern 1144, respectively.

However, the structure of the second package 12 is not limited to the example embodiments as disclosed above, and the structure of the second package 12 may be varied and/or modified depending on application and/or design. Some example embodiments of the second package 12 are described below.

The heat dissipation device 13 may be disposed in the first region A and on the upper side of the first package 11 to which the (1-1)-th semiconductor chip 111 is mounted. The cross-sectional area of the heat dissipation device 13 may be the same as the cross-sectional area of the (1-1)-th semiconductor chip 111. In some example embodiments, a cross-sectional area may refer to the area of the lower surface of the heat dissipation device 13 formed in the first direction D₁ and the second direction D₂ and the area of the upper surface of the (1-1)-th semiconductor chip 111.

The heat dissipation device 13 may include a heat spreader, a heat slug, a heat sink, a vapor chamber, and the like. The heat dissipation device 13 may be formed of or may include a metal material such as copper (Cu), aluminum (Al), stainless steel (SUS), and the like, but example embodiments are not limited thereto.

The lower surface of the heat dissipation device 13 may face the upper surface of the (1-1)-th semiconductor chip 111, and the heat dissipation device 13 may be in contact (e.g., in thermal contact) with the upper surface of the (1-1)-th semiconductor chip 111. The heat generated from the (1-1)-th semiconductor chip 111 may be efficiently and/or effectively dissipated via the heat dissipation device 13.

The semiconductor package 1A may further include a thermal interface material (TIM) layer 14 disposed between the upper surface of the (1-1)-th semiconductor chip 111 and the lower surface of the heat dissipation device 13.

The TIM layer 14 may efficiently and/or effectively transfer heat from the (1-1)-th semiconductor chip 111 to the heat dissipation device 13 and may function as or operate as an adhesive layer between the (1-1)-th semiconductor chip 111 and the heat dissipation device 13. The stability and/or mechanical reliability of the semiconductor package 1A may be improved and/or increased by the TIM layer 14.

The ratio of the proportion of the first region A to the proportion of the second region B within the first package 11 may be 1:1. The size of the (1-1)-th semiconductor chip 111 mounted in the first region A may be greater than the size of the (1-2)-th semiconductor chip 112 mounted in the second region B. The amount of heat generated in the first region A of the first package 11 may be greater than the amount of heat generated in the second region B of the first package 11. According to some example embodiments, heat generated in the first region A may be reduced, minimized and/or lowered by the heat dissipation device 13 on the upper side of the first region A of the first package 11.

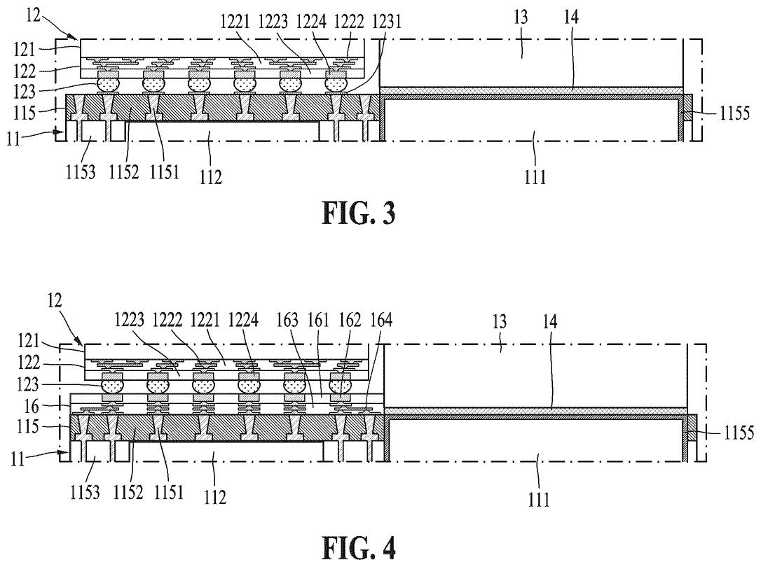

FIG. 3 is an enlarged view illustrating a portion “X” of FIG. 2, according to some example embodiments.

Referring to FIG. 3, the upper surface of the (1-1)-th semiconductor chip 111 may be on the same plane as the upper surface of the first package 11. The upper surface of the (1-1)-th semiconductor chip 111 may not be embedded in the first package 11 but instead may be exposed on the upper surface of the first package 11. The (1-1)-th semiconductor chip 111 and the heat dissipation device 13 may be in direct contact with each other on the outer surface or exterior of the first package 11 rather than the inside of the first package 11. This structure may reduce and/or minimize the heat generated from the (1-1)-th semiconductor chip 111 from being transmitted or transferred to the inside or interior of the first package 11, and the heat may be effectively transferred to the outside of the first package 11.

For the second package 12, the lower surface of the second package 12 may be in direct contact with the upper surface of the second region B of the first package 11. In some example embodiments, a separate interposer or backside RDL (BRDL) may not be disposed between the second package 12 and the first package 11. A direct electrical connection may be formed between the first package 11 and the second package 12. This structure or configuration may reduce and/or minimize manufacturing costs and/or the turnaround time (TAT) in implementing a package on package (PoP).

FIG. 4 illustrates an example embodiment in which a BRDL 16 is disposed between the first package 11 and the second package 12. The view in FIG. 4 is the same as the view of the portion “X” of FIG. 2.

Referring to FIG. 4, in some example embodiments, the BRDL 16 may be disposed between the first package 11 and the second package 12. The first package 11 and the second package 12 may be electrically connected to each other by the BRDL 16. A separate interposer instead of the BRDL 16 may be disposed between the first package 11 and the second package 12.

For example, the BRDL 16 may include a (7-1)-th redistributed insulating layer 161, a (7-2)-th redistributed insulating layer 163 disposed on the lower side of the (7-1)-th redistributed insulating layer 161, a seventh bump pattern 162 disposed in the (7-1)-th redistributed insulating layer 161, and a seventh redistributed pattern 164 disposed in the (7-2)-th redistributed insulating layer 163.

The seventh bump pattern 162 may be disposed on the uppermost side of the BRDL 16. The upper surface of the seventh bump pattern 162 may not be covered by the (7-1)-th redistributed insulating layer 161. The seventh bump 162 may function as a pad disposed on the lower side of the second connecting terminal 123. A plurality of seventh bump patterns 162 may be spaced apart from one another side by side and may be electrically insulated from one another. The seventh bump patterns 162 are spaced apart from each other in the second direction D₂ parallel to the lower surface of the BRDL 16.

The seventh redistributed pattern 164 may be disposed on the lower side of the seventh bump pattern 162. The seventh redistributed pattern 164 may be electrically connected to the seventh bump pattern 162. The seventh redistributed pattern 164 may be electrically connected to the first wiring pattern 1151 of the first package 11. A plurality of seventh redistributed patterns 164 disposed in a straight line in the second direction D₂ may be spaced apart and electrically separated from one another. Some of the plurality of seventh redistributed patterns 164, which are disposed at different levels in the third direction D₃, may be electrically connected to one another.

The seventh redistributed pattern 164 may include a seventh via portion and a seventh wiring portion. The seventh via portion may be configured for providing a vertical connection and the seventh wiring portion may be configured for providing a horizontal connection. The seventh via portion may be a portion of the seventh redistributed pattern 164 extending in the third direction D₃ and the seventh wiring portion may be a portion of the seventh redistributed pattern 164 extending in the second direction D₂. In some example embodiments, the width of the seventh wiring portion may be greater than the width of the seventh via portion.

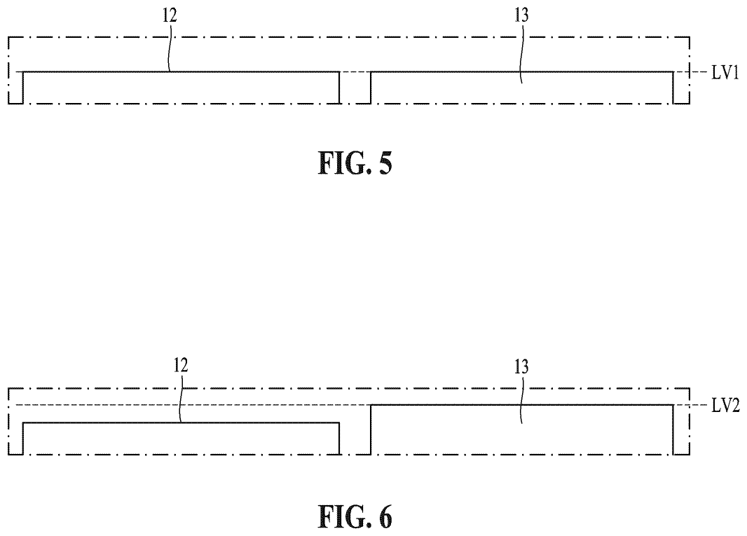

FIG. 5 is an enlarged view of a portion “Y” of FIG. 2, according to some example embodiments.

Referring to FIG. 5, the upper surface of the heat dissipation device 13 and the upper surface of the second package 12 may be disposed at a same height or level indicated by position LV1. The upper surface of the heat dissipation device 13 and the upper surface of the second package 12 may be disposed side by side in the same plane.

FIG. 6 is an enlarged view of a portion “Y” of FIG. 2, according to some example embodiments. As illustrated in FIG. 6, the upper surface of the heat dissipation device 13 is at a higher level than the upper surface of the second package 12.

Referring to FIG. 6, the upper surface of the heat dissipation device 13 may be at a level LV2 that is higher than the upper surface of the second package 12, which may indicate that the thickness in the height direction of the heat dissipation device 13 is relatively greater than the thickness of the second package 12. The heat dissipation performance of the heat dissipation device 13 may be further improved, increased and/or maximized.

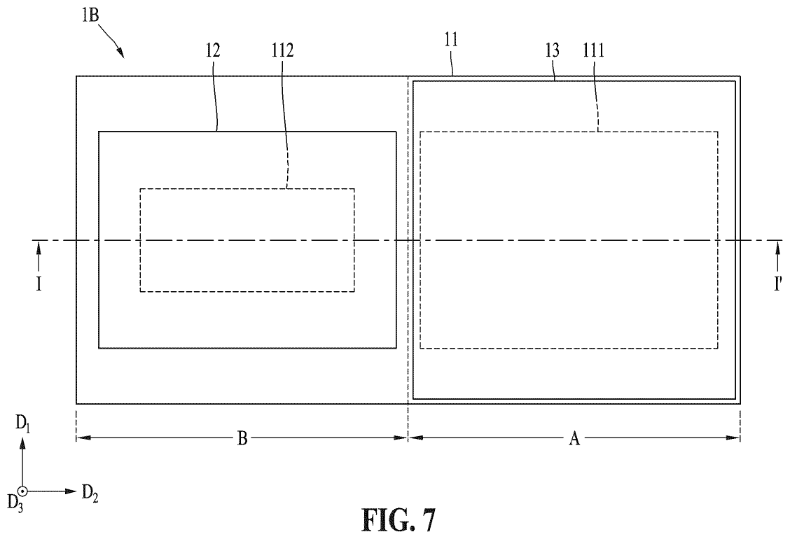

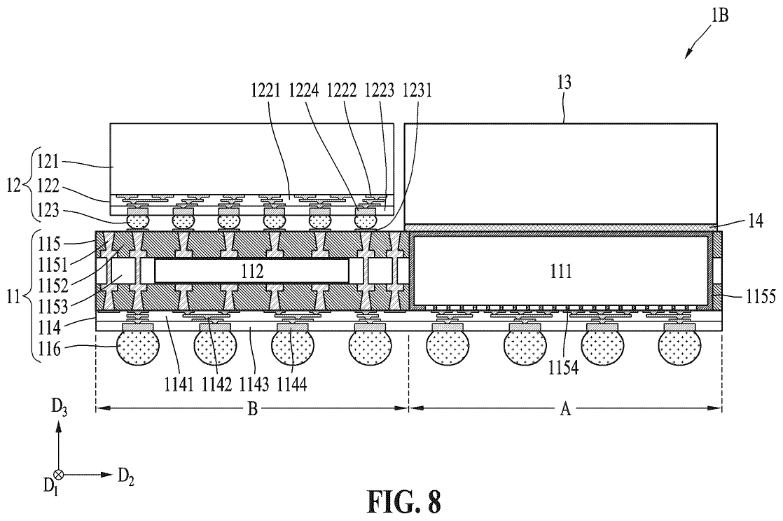

FIG. 7 is a plan view illustrating a semiconductor package 1B, according to some example embodiments. FIG. 8 is a cross-sectional view taken along a line I-I′ of FIG. 7. The semiconductor package 1B of FIGS. 7 and 8 may be similar in some respects to the semiconductor package 1A of FIGS. 1 and 2, and therefore may be best understood with reference thereto where like numerals indicate like elements not described again in detail.

Referring to FIGS. 7 and 8, the cross-sectional area of the heat dissipation device 13 of the semiconductor package 1B may be greater than the cross-sectional area of the (1-1)-th semiconductor chip 111. In other words, the area of the lower surface of the heat dissipation device 13 of the semiconductor package 1B may be greater than the area of the upper surface of the (1-1)-th semiconductor chip 111. As the total volume of the heat dissipation device 13 is relatively larger, the semiconductor package 1B may have an improved, higher, and/or maximized thermal conduction performance. In some example embodiments, the cross-sectional area of the heat dissipation device 13 may be same as the cross-sectional area of the first region A of the first package 11.

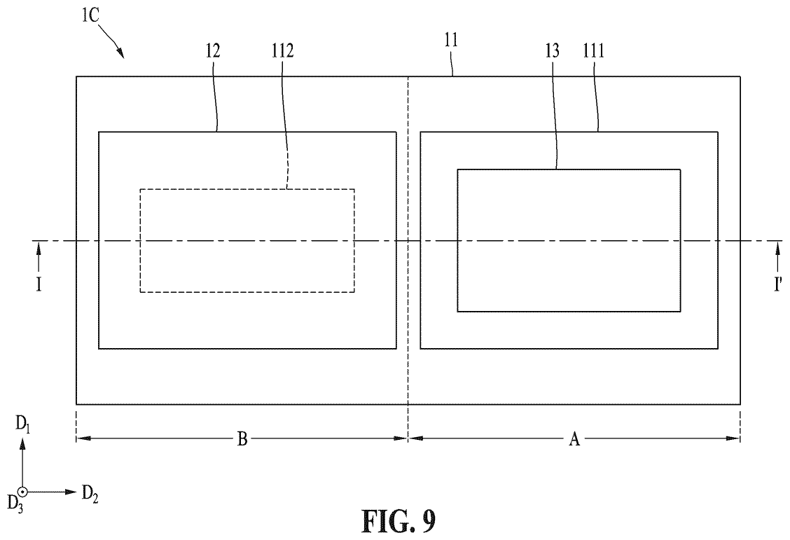

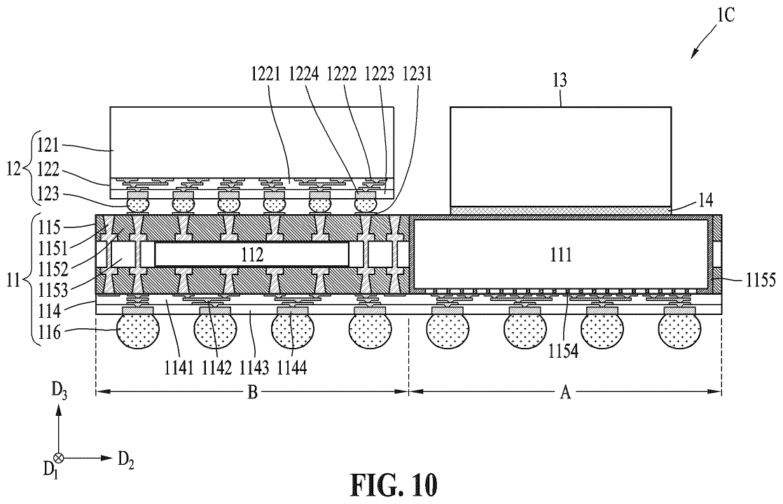

FIG. 9 is a plan view illustrating a semiconductor package 1C, according to some example embodiments. FIG. 10 is a cross-sectional view taken along a line I-I′ of FIG. 9. The semiconductor package 1C of FIGS. 9 and 10 may be similar in some respects to the semiconductor package 1A of FIGS. 1 and 2, and therefore may be best understood with reference thereto where like numerals indicate like elements not described again in detail.

Referring to FIGS. 9 and 10, the cross-sectional area of the heat dissipation device 13 of the semiconductor package 1C may be less than the cross-sectional area of the (1-1)-th semiconductor chip 111. In other words, the area of the lower surface of the heat dissipation device 13 of the semiconductor package 1C may be lesser than the area of the upper surface of the (1-1)-th semiconductor chip 111. As the total volume of the heat dissipation device 13 is relatively smaller or lower, the semiconductor package 1C may be more compact.

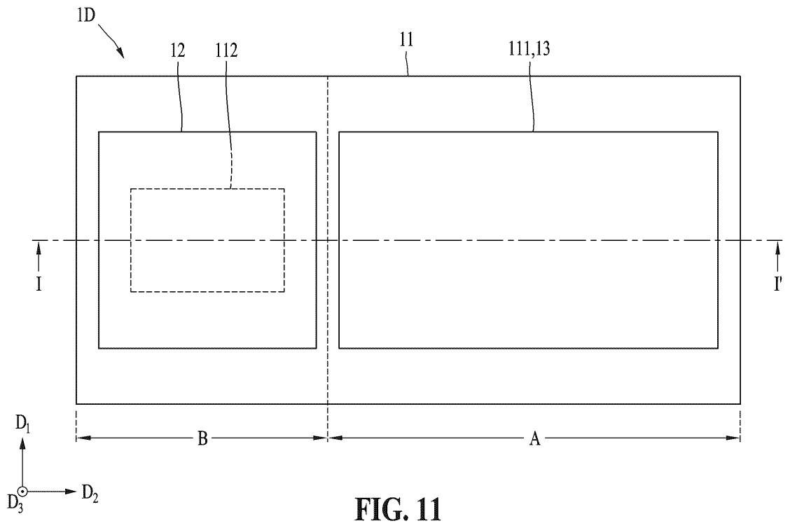

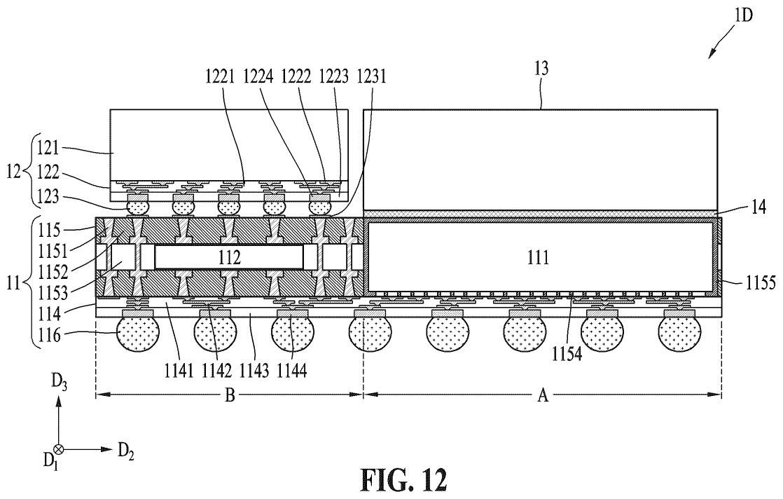

FIG. 11 is a plan view illustrating a semiconductor package 1D, according to some example embodiments. FIG. 12 is a cross-sectional view taken along a line I-I′ of FIG. 11. The semiconductor package 1D of FIGS. 11 and 12 may be similar in some respects to the semiconductor package 1A of FIGS. 1 and 2, and therefore may be best understood with reference thereto where like numerals indicate like elements not described again in detail.

Referring to FIGS. 11 and 12, within the first package 11 of the semiconductor package 1D, the size or dimensions of the first region A may be greater than the size or dimensions of the second region B. In some example embodiments, the size of the (1-1)-th semiconductor chip 111 mounted to the first region A of the first package 11 may be greater than the size of the (1-2)-th semiconductor chip 112 mounted to the second region B. In some example embodiments, the size of the heat dissipation device 13 disposed on the upper side of the first region A may also be relatively larger to correspond to the (1-1)-th semiconductor chip 111. In other words, the semiconductor package 1D and the heat dissipation device 13 may occupy a relatively larger area of the first package 11 compared to the (1-2)-th semiconductor chip 112. The (1-2)-th semiconductor chip 112 may be relatively smaller, and the second package 12 disposed on the upper side of the second region B may be more compact.

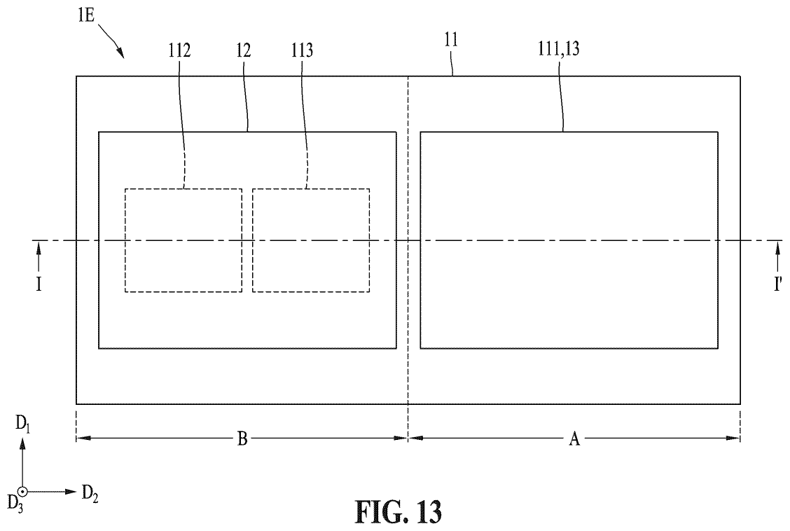

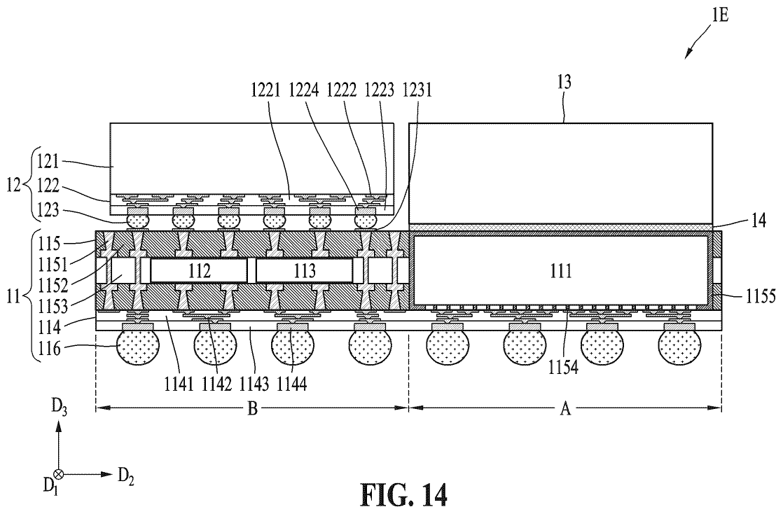

FIG. 13 is a plan view illustrating a semiconductor package 1E, according to some example embodiments. FIG. 14 is a cross-sectional view taken along a line I-I′ of FIG. 13. The semiconductor package 1D of FIGS. 13 and 14 may be similar in some respects to the semiconductor package 1A of FIGS. 1 and 2, and therefore may be best understood with reference thereto where like numerals indicate like elements not described again in detail.

Referring to FIGS. 13 and 14, the first package 11 of a semiconductor package 1E may further include a (1-3)-th semiconductor chip 113 mounted to the second region B. The (1-2)-th semiconductor chip 112 and the (1-3)-th semiconductor chip 113 may be both mounted to the second region B of the first package 11. The (1-2)-th semiconductor chip 112 and the (1-3)-th semiconductor chip 113 may be of the same type or of different types.

In some example embodiments, and as illustrated, the size (e.g., cross-sectional area) of the (1-2)-th semiconductor chip 112 is the same as the size (e.g., cross-sectional area) of the (1-3)-th semiconductor chip 113, but example embodiments are not limited thereto. In some example embodiments, the size (e.g., cross-sectional area) of the (1-2)-th semiconductor chip 112 may be different from the size (e.g., cross-sectional area) of the (1-3)-th semiconductor chip 113. In some example embodiments, the sizes (e.g., cross-sectional areas) of the (1-2)-th semiconductor chip 112 and the (1-3)-th semiconductor chip 113 may be less than the size (e.g., cross-sectional area) of the (1-1)-th semiconductor chip 111.

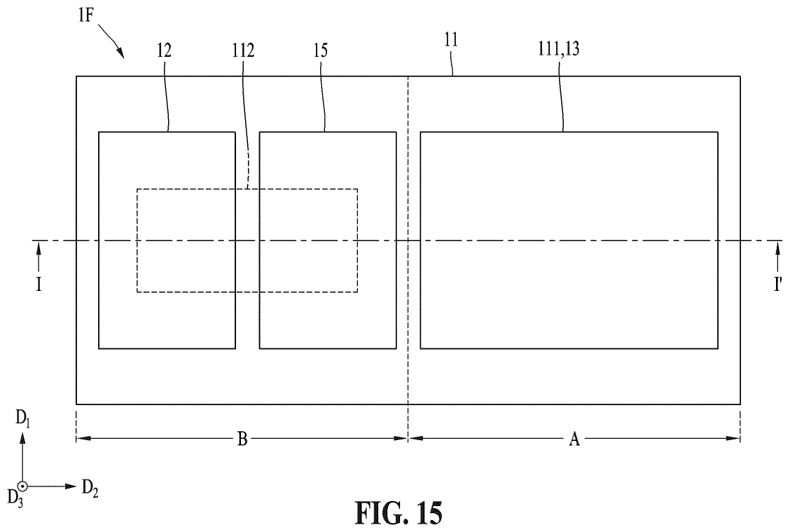

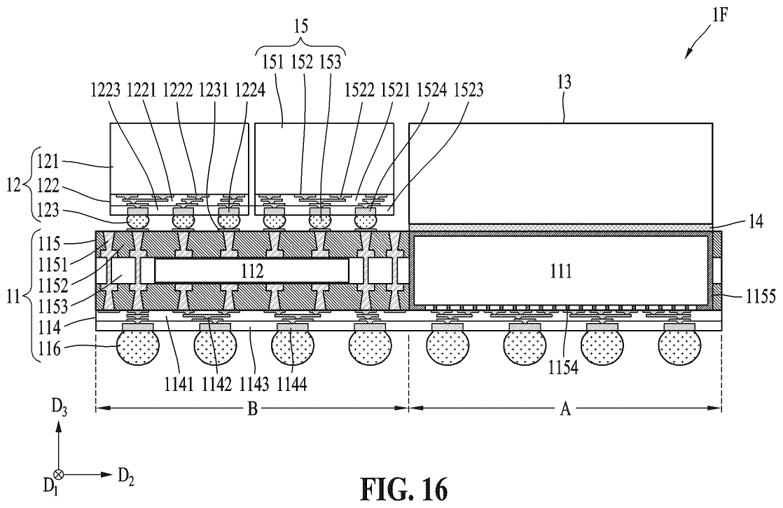

FIG. 15 is a plan view illustrating a semiconductor package 1F, according to some example embodiments. FIG. 16 is a cross-sectional view taken along a line I-I′ of FIG. 15. The semiconductor package 1F of FIGS. 15 and 16 may be similar in some respects to the semiconductor package 1A of FIGS. 1 and 2, and therefore may be best understood with reference thereto where like numerals indicate like elements not described again in detail.

Referring to FIGS. 15 and 16, the semiconductor package 1F may further include a third package 15. The third package 15 may include at least one semiconductor chip.

The third package 15 may be disposed in the second region B and on the upper side of the first package 11 to which the (1-2)-th semiconductor chip 112 is mounted. The third package 15 may include a third package substrate 151, a third RDL 152, and a third connecting terminal 153. The third package substrate 151 may include at least one third semiconductor chip and a third insulating layer filling the inside (or interior) of the third package substrate 151 and the third insulating layer may at least in part form the third package 15. The third package substrate 151 may be disposed on one (or upper) surface of the third RDL 152. The third connecting terminal 153 may be disposed on the other (or lower) surface of the third RDL 152. The second pad 1231 may also be disposed on the lower side of the third connecting terminal 153. The third connecting terminal 153 may be electrically connected to the first wiring pattern 1151 of the first package 11 via the second pad 1231.

For example, the third RDL 152 may include a (3-1)-th redistributed insulating layer 1521, a (3-2)-th redistributed insulating layer 1523 disposed on the lower side of the (3-1)-th redistributed insulating layer 1521, a plurality of third redistributed patterns 1522 disposed in the (3-1)-th redistributed insulating layer 1521, and a third bump pattern 1524 disposed in the (3-2)-th redistributed insulating layer 1523.

The (3-1)-th redistributed insulating layer 1521, the (3-2)-th redistributed insulating layer 1523, the third redistributed pattern 1522, and the third bump pattern 1524 may be similar in some respects to the (1-1)-th redistributed insulating layer 1141, the (1-2)-th redistributed insulating layer 1143, the first redistributed pattern 1142, and the first bump pattern 1144, respectively, and a discussion thereof is omitted herein for the sake of brevity.

The structure of the third package 15 is not limited to the structure illustrated in FIGS. 15 and 16 and the structure may be modified depending on application and/or design.

In some example embodiments, and as illustrated, that the size (e.g., cross-sectional area, volume, or the like) of the second package 12 is the same as the size (e.g., cross-sectional area, volume, or the like) of the third package 15, but example embodiments are not limited thereto. In some example embodiments, the size of the second package 12 may be different from the size of the third package 15. In some example embodiments, the size (e.g., cross-sectional area, volume, or the like) of the second semiconductor chip and the size (e.g., cross-sectional area, volume, or the like) of the third semiconductor chip mounted to the second package 12 and the third package 15, respectively, may be the same or different.

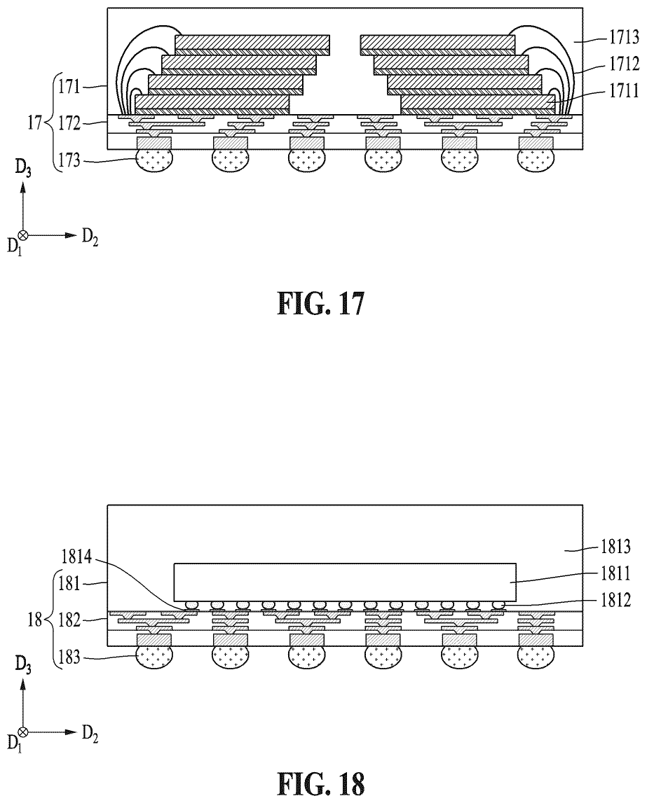

FIGS. 17 to 19 are cross-sectional views illustrating the second package 12 or the third package 15 of a semiconductor package, according to some example embodiments.

For convenience of description, packages illustrated in FIGS. 17 to 19 are referred to as a fourth package 17, a fifth package 18, and a sixth package 19, respectively. Each of the second package 12 and the third package 15 of the above-described semiconductor package may be formed in one of the fourth package 17, the fifth package 18, and the sixth package 19 as described below. The structure of the second package 12 and the structure of the third package 15 may be the same or different. However, example embodiments are not limited thereto, and the second package 12 or the third package 15 may have other structures or configurations depending on application and/or design.

Referring to FIG. 17, the fourth package 17 may be a memory semiconductor package, for example, a wire bonding package. The fourth package 17 may include at least one semiconductor chip.

The fourth package 17 may include a fourth package substrate 171, a fourth RDL 172, and a fourth connecting terminal 173. The fourth package substrate 171 may include a plurality of fourth semiconductor chips 1711. The fourth package substrate 171 may be disposed on one (or upper) surface of the fourth RDL 172. The fourth connecting terminal 173 may be disposed on the other (or lower) surface of the fourth RDL 172.

For example, the fourth RDL 172 may include a (4-1)-th redistributed insulating layer, a (4-2)-th redistributed insulating layer disposed on the lower side of the (4-1)-th redistributed insulating layer, a plurality of fourth redistributed patterns disposed in the (4-1)-th redistributed insulating layer, and a fourth bump pattern disposed in the (4-2)-th redistributed insulating layer.

The (4-1)-th redistributed insulating layer, the (4-2)-th redistributed insulating layer, the fourth redistributed pattern, and the fourth bump pattern may be similar in some respects to the (1-1)-th redistributed insulating layer 1141, the (1-2)-th redistributed insulating layer 1143, the first redistributed pattern 1142, and the first bump pattern 1144, respectively, and a discussion thereof is omitted herein for the sake of brevity.

The fourth package substrate 171 may include a plurality of wires 1712 that electrically connect each of the fourth semiconductor chips 1711 to the fourth redistributed layer 172. For example, the plurality of wires 1712 may be electrically connected to the fourth redistributed pattern of the fourth RDL 172. In some example embodiments, a wire may be formed of gold (Au), copper (Cu), or the like. The fourth package substrate 171 may include a fourth insulating layer 1713 filling the inside or the interior of the fourth package substrate 171 and at least in part forming the fourth package 17.

Referring to FIG. 18, the fifth package 18 may be a non-memory semiconductor package and may be a flip-chip package. The fifth package 18 may include at least one semiconductor chip.

The fifth package 18 may include a fifth package substrate 181, a fifth RDL 182, and a fifth connecting terminal 183. The fifth package substrate 181 may include a fifth semiconductor chip 1811. The fifth package substrate 181 may be disposed on one surface of the fifth RDL 182. The fifth connecting terminal 183 may be disposed on the other surface of the fifth RDL 182.

The fifth package substrate 181 may include a seventh connecting terminal 1812 that electrically connects the fifth semiconductor chip 1811 to the fifth RDL 182. The fifth package substrate 181 may include a fifth insulating layer 1813 filling the inside of the fifth package substrate 181, and at least partly forming the fifth package 18. A third pad 1814 may be disposed on the lower side of the seventh connecting terminal 1812. The seventh connecting terminal 1812 may be electrically connected to the fifth RDL 182 via the third pad 1814.

For example, the fifth RDL 182 may include a (5-1)-th redistributed insulating layer, a (5-2)-th redistributed insulating layer disposed on the lower side of the (5-1)-th redistributed insulating layer, a plurality of fifth redistributed patterns disposed in the (5-1)-th redistributed insulating layer, and a fifth bump pattern disposed in the (5-2)-th redistributed insulating layer.

The (5-1)-th redistributed insulating layer, the (5-2)-th redistributed insulating layer, the fifth redistributed pattern, and the fifth bump pattern may be similar in some respects to the (1-1)-th redistributed insulating layer 1141, the (1-2)-th redistributed insulating layer 1143, the first redistributed pattern 1142, and the first bump pattern 1144 described above, respectively, and a discussion thereof is omitted herein for the sake of brevity.

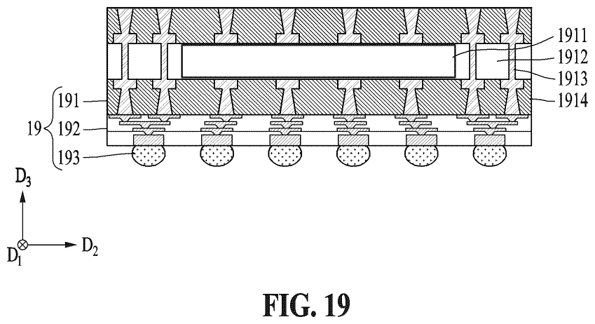

Referring to FIG. 19, the sixth package 19 may include a sixth package substrate 191, a sixth RDL 192, and a sixth connecting terminal 193. The sixth package substrate 191 may include a sixth semiconductor chip 1911. The sixth package substrate 191 may be disposed on one (or upper) surface of the sixth RDL 192. The sixth connecting terminal 193 may be disposed on the other (or lower) surface of the sixth RDL 192.

The sixth semiconductor chip 1911 may be disposed in a second core layer 1912 of the sixth package substrate 191. The sixth package substrate 191 may include a second wiring pattern 1913 and a sixth insulating layer 1914. The second wiring pattern 1913 may be formed in the sixth package substrate 191 and electrically connected to the sixth semiconductor chip 1911. The sixth insulating layer 1914 may fill the inside of the sixth package substrate 191. The second wiring pattern 1913 may electrically connect the sixth semiconductor chip 1911 to the sixth RDL 192.

For example, the sixth RDL 192 may include a (6-1)-th redistributed insulating layer, a (6-2)-th redistributed insulating layer disposed on the lower side of the (6-1)-th redistributed insulating layer, a plurality of sixth redistributed patterns disposed in the (6-1)-th redistributed insulating layer, and a sixth bump pattern disposed in the (6-2)-th redistributed insulating layer. The sixth redistributed pattern of the sixth RDL 192 may be electrically connected to the second wiring pattern 1913.

The (6-1)-th redistributed insulating layer, the (6-2)-th redistributed insulating layer, the sixth redistributed pattern, and the sixth bump pattern may be similar in some respects to the (1-1)-th redistributed insulating layer 1141, the (1-2)-th redistributed insulating layer 1143, the first redistributed pattern 1142, and the first bump pattern 1144 described above, respectively, and a discussion thereof is omitted herein for the sake of brevity.

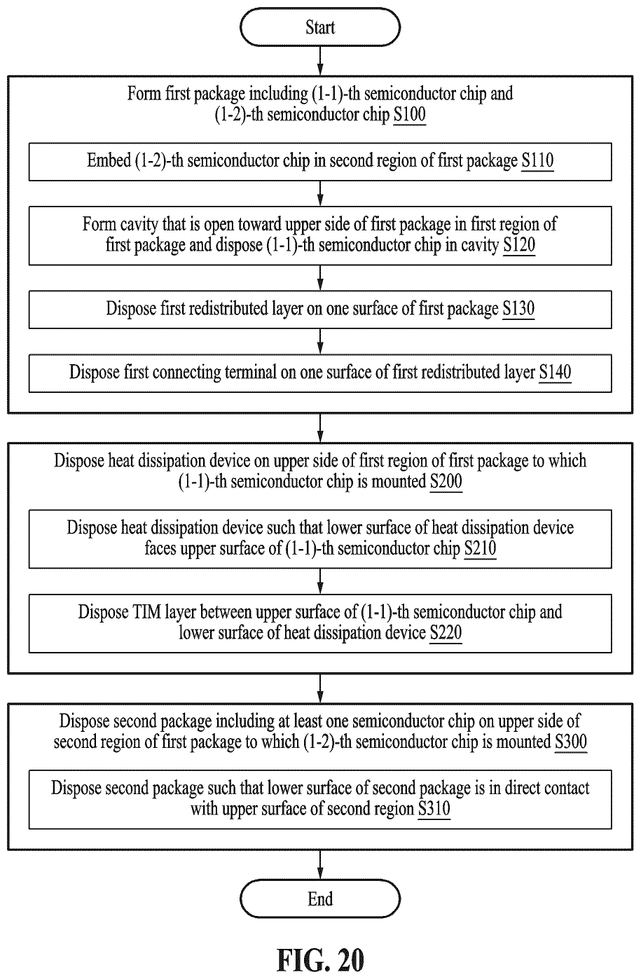

FIG. 20 is a flowchart of a method of manufacturing a semiconductor package, according to some example embodiments. It is understood that additional operations can be provided before, during, and after the operations in FIG. 20, and, in some example embodiments, some of the operations described below can be replaced or eliminated. The order of the operations/processes may be interchangeable, or two or more operations can be performed simultaneously.

Referring to FIG. 20, the method of manufacturing a semiconductor package may include operation S100 of forming a first package including a (1-1)-th semiconductor chip and a (1-2)-th semiconductor chip, operation S200 of disposing a heat dissipation device on the upper side of a first region of the first package to which the (1-1)-th semiconductor chip is mounted, and operation S300 of disposing a second package, which includes at least one semiconductor chip, on the upper side of a second region of the first package to which the (1-2)-th semiconductor chip is mounted.

Operation S100 of forming the first package may include operation S110 of embedding the (1-2)-th semiconductor chip in the second region of the first package and operation S120 of forming a cavity that is open toward the upper side of the first package in the first region of the first package and disposing the (1-1)-th semiconductor chip in the cavity.

Operation S100 of forming the first package may further include operation $130 of disposing a first RDL on one surface of the first package and operation S140 of disposing a first connecting terminal on one surface of the first RDL.

Operation S100 of forming the first package may include setting the ratio of the first region to the second region of the first package to be 1:1 or forming the proportion of the first region to be greater than the proportion of the second region within the first package.

Operation S200 of disposing the heat dissipation device may include operation S210 of disposing the heat dissipation device such that the lower surface of the heat dissipation device faces the upper surface of the (1-1)-th semiconductor chip. In some example embodiments, the lower surface of the heat dissipation device may be in direct contact with the upper surface of the (1-1)-th semiconductor chip.

Operation S200 of disposing the heat dissipation device may further include operation S220 of disposing a thermal interface material (TIM) layer between the upper surface of the (1-1)-th semiconductor chip and the lower surface of the heat dissipation device.

Operation S300 of disposing the second package may include operation S310 of disposing the second package such that the lower surface of the second package is in direct contact with the upper surface of the second region of the first package.

The method of manufacturing a semiconductor package may also include disposing a third package, which includes at least one semiconductor chip, on the upper side of the second region of the first package to which the (1-2)-th semiconductor chip is mounted.

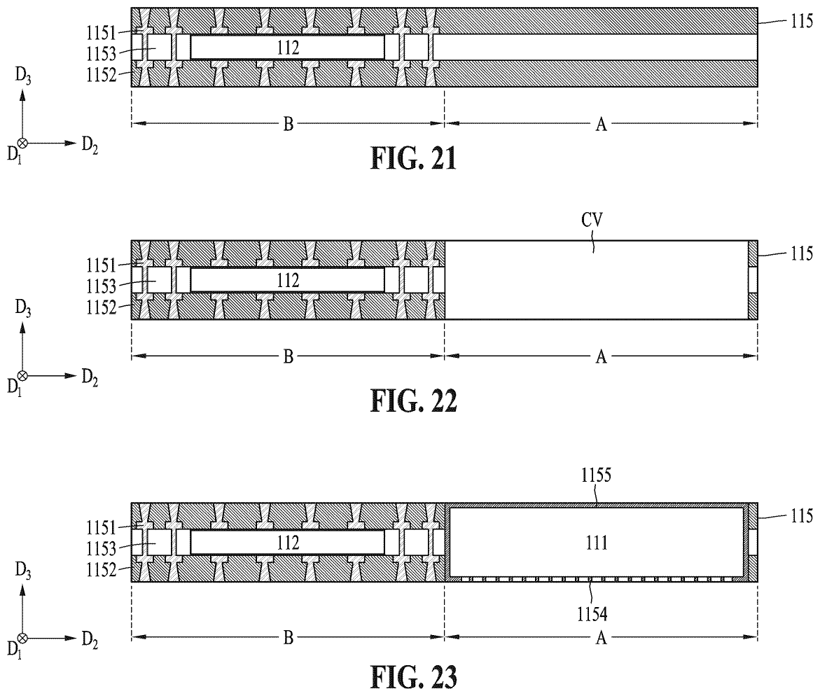

FIGS. 21 to 26 illustrate operations in a method of manufacturing a semiconductor package, according to some example embodiments. It is understood that additional operations can be provided before, during, and after the operations in FIGS. 21-26, and, in some example embodiments of the method, some of the operations described below can be replaced or eliminated. The order of the operations/processes may be interchangeable, or two or more operations can be performed simultaneously.

Referring to FIG. 21, a portion inside the first package substrate 115 may be filled with the first insulating layer 1152. The (1-2)-th semiconductor chip 112 may be disposed in the first core layer 1153 formed on the second region B of the first package substrate 15. The (1-2)-th semiconductor chip 112 may be embedded in the second region B of the first package 11. The first wiring pattern 1151 may be formed in the first package substrate 115 and electrically connected to the (1-2)-th semiconductor chip 112.

Referring to FIG. 22, a cavity CV for mounting the (1-1)-th semiconductor chip 111 on the first region A of the first package substrate 115 may be formed. The cavity CV may be open or exposed toward the upper side of the first package substrate 115.

Referring to FIG. 23, the (1-1)-th semiconductor chip 111 may be disposed in the cavity CV formed on the first region A of the first package substrate 115. The upper surface of the (1-1)-th semiconductor chip 111 may be exposed on the upper surface of the first region A of the first package 11. The first pad 1154 may be formed in the first package substrate 115 and electrically connected to the (1-1)-th semiconductor chip 111. The molding 1155 may surround the periphery of the (1-1)-th semiconductor chip 111.

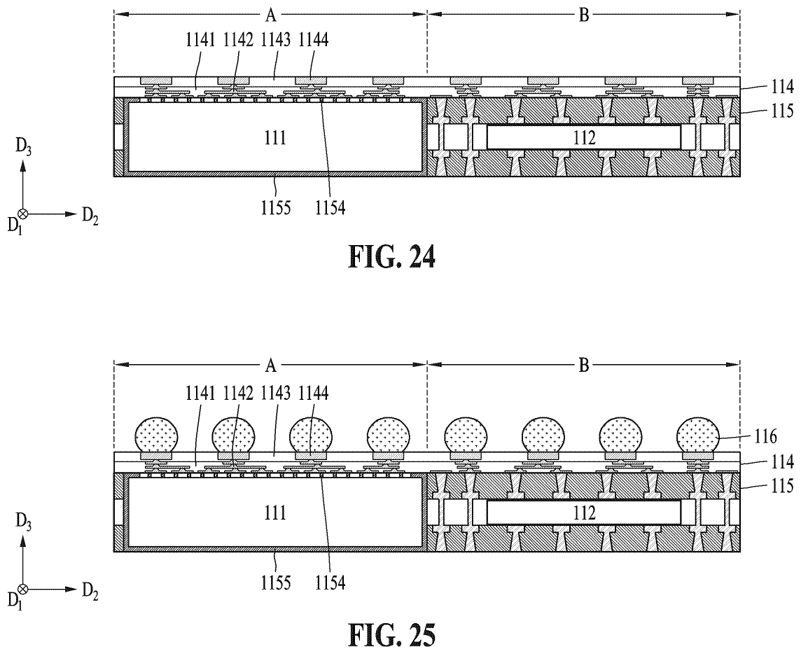

Referring to FIG. 24, the first package substrate 115 may be flipped (e.g., sideways in FIG. 24) and the first RDL 114 may be disposed on one surface of the first package substrate 115. The first pad 1154 may electrically connect the (1-1)-th semiconductor chip 111 to the first RDL 114. The first wiring pattern 1151 may electrically connect the (1-2)-th semiconductor chip 112 to the first RDL 114. The (1-1)-th semiconductor chip 111 and the (1-2)-th semiconductor chip 112 may be electrically connected to each other through the first pad 1154, the first wiring pattern 1151, and the first RDL 114.

Referring to FIG. 25, the first connecting terminal 116 may be disposed on the other surface of the first RDL 114.

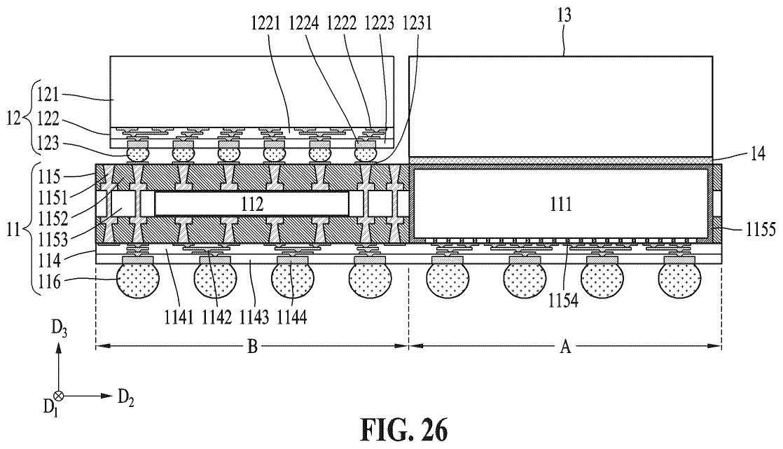

Referring to FIG. 26, the first package substrate 115 may be flipped (e.g., vertically) and the first connecting terminal 116 of the first package 11 may be disposed to face downward. Then, the second package 12 including the second package substrate 121, the second RDL 122, and the second connecting terminal 123 may be disposed on the upper side of the second region B of the first package 11 on which the (1-2)-th semiconductor chip 112 is mounted. The second pad 1231 may be disposed on the lower side of the second connecting terminal 123. The second connecting terminal 123 may be electrically connected to the first wiring pattern 1151 of the first package 11 via the second pad 1231. The heat dissipation device 13 may be disposed on the upper side of the first region A of the first package 11 to which the (1-1)-th semiconductor chip 111 is mounted.

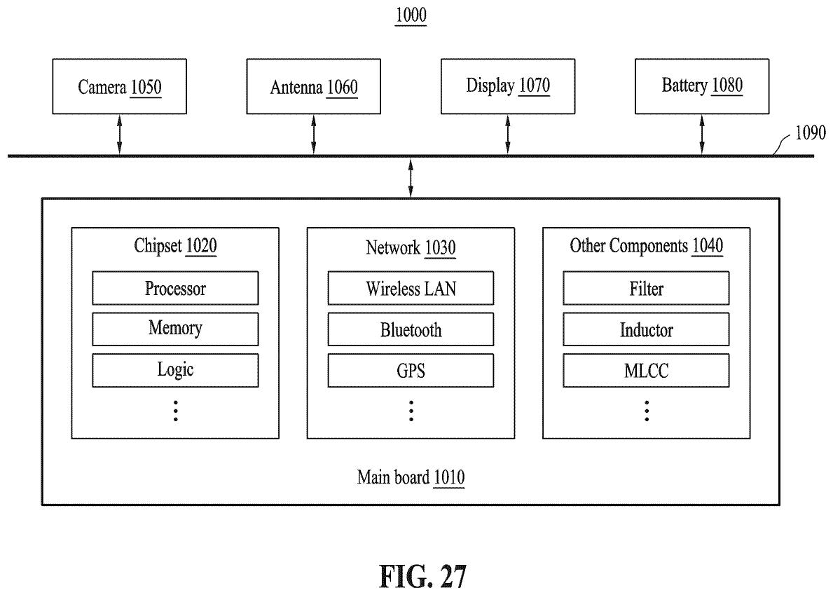

FIG. 27 illustrates an electronic device system including a semiconductor package according to some example embodiments.

Referring to FIG. 27, an electronic device 1000 may include a main board 1010. A chipset 1020, a network 1030, other components 1040, and the like may be physically and/or electrically connected to the main board 1010. These components may be electrically connected to other electronic components (e.g., electronic components described below) via a bus 1090.

The chipset 1020 may include a memory chip such as volatile memory, non-volatile memory, flash memory, and the like, an application processor chip such as a central processor, a graphics processor, a digital signal processor, an encryption processor, a microprocessor, a microcontroller, and the like, and a logic chip such as an A/D converter, an ASIC, and the like. In addition, other types of chip-related electronic components may be included. The components of the chipset 1020 may be individual or discrete components, or two or more components may be combined with each other.

The network 1030 may include any wired or wireless protocols such as wireless fidelity (Wi-Fi) (e.g., IEEE 802.11 family, etc.), worldwide interoperability for microwave access (WiMAX) (e.g., IEEE 802.16 family, etc.), IEEE 802.20, long term evolution (LTE), evolution-data optimized (Ev-DO), evolved high speed packet access (HSPA+), evolved high speed downlink packet access (HSDPA+), evolved high-speed uplink packet access (HSUPA+), edge, global system for mobile communications (GSM), global positioning system (GPS), general packet radio service (GPRS), code-division multiple access (CDMA), time division multiple access (TDMA), digital enhanced cordless telecommunications (DECT), Bluetooth, third generation (3G), 4G, 5G, and any subsequent protocols. Additionally, any other wired or wireless standards or protocols may be included. The components of the network 1030 may be individual or discrete components, or two or more components may be combined with each.

The other components 1040 may include a high-frequency inductor, a ferrite inductor, a power inductor, a ferrite bead, low temperature co-fired ceramics (LTCC), an electromagnetic interference (EMI) filter, and a multi-layer ceramic condenser (MLCC). Additionally, various other passive components used for different purposes may also be included. The other components 1040 may be individual or discrete components, two or more of the other components 1040 may be combined with each other.

The electronic device 1000 may include other electronic components that may or may not be physically and/or electrically connected to the main board 1010. The other electronic components may be, for example, a camera 1050, an antenna 1060, a display 1070, and/or a battery 1080. The other electronic components may further include an audio codec, a video codec, a power amplifier, a compass, an accelerometer, a gyroscope, a speaker, a mass storage device, a compact disk, a digital versatile disk (DVD), and the like. In addition, electronic components and the like used for various purposes may be included according to the type of the electronic device 1000.

The electronic device 1000 may be a smartphone, a personal digital assistant, a digital video camera, a digital still camera, a network system, a computer, a monitor, a tablet, a laptop, a netbook, a television, a video game, a smartwatch, and the like. In some example embodiments, the electronic device 1000 may be an electronic device configured for processing data.

The semiconductor packages 1A, 1B, 1C, 1D, and 1E, according to some example embodiments, described above with reference to FIGS. 1 to 14 may be used in electronic devices 1000.

According to some example embodiments, a semiconductor package and a method of manufacturing the semiconductor package may increase and/or improve the cooling efficiency of a semiconductor chip mounted in a first package, thereby reducing and/or minimizing the thermal coupling between semiconductor chips.

In addition, the semiconductor package and the method of manufacturing the semiconductor package according to some example embodiments may omit an additional interposer or RDL that may be disposed between the first package and the second package when the second package is stacked on the upper side of the first package, thereby implementing a PoP having reduced manufacturing costs and/or turn around time (TAT).

The semiconductor package and the method of manufacturing the semiconductor package according to some example embodiments may improve and/or increase thermal characteristics by maximizing and/or improving the heat dissipation of the semiconductor chip. Furthermore, by effectively packaging multiple semiconductor chips, the overall system resistance may be reduced and/or operating speed may be increased and/or maximized, thereby improving and/or increasing electrical characteristics.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While inventive concepts have been particularly shown and described with reference to embodiments thereof, it will be understood that various change in form and details may be made therein without departing from the spirit and scope of the following claims. Further, example embodiments are not necessarily mutually exclusive with one another. For example, some example embodiments may include one or more features described with reference to one or more figures, and may also include one or more other features described with reference to one or more other figures.

1. A semiconductor package comprising:
a first package including at least two semiconductor chips;
a second package including at least one semiconductor chip and on an upper side of the first package; and
a heat dissipation device on the upper side of the first package, wherein
the heat dissipation device is on an upper side in a first region of the first package in which a (1-1)-th semiconductor chip is mounted,
the second package is on an upper side in a second region of the first package in which a (1-2)-th semiconductor chip is mounted,
a cavity that is exposed to the heat dissipation device is defined in the first region of the first package, and the (1-1)-th semiconductor chip is disposed in the cavity, and
the (1-2)-th semiconductor chip is in the second region of the first package.

2. The semiconductor package of claim 1, wherein a lower surface of the heat dissipation device faces an upper surface of the (1-1)-th semiconductor chip.

3. The semiconductor package of claim 2, wherein the upper surface of the (1-1)-th semiconductor chip is in a same plane as an upper surface of the first package.

4. The semiconductor package of claim 3, further comprising:
a thermal interface material (TIM) layer between the upper surface of the (1-1)-th semiconductor chip and the lower surface of the heat dissipation device.

5. The semiconductor package of claim 1, wherein a lower surface of the second package is in direct contact with an upper surface of the first package.

6. The semiconductor package of claim 1, wherein an upper surface of the heat dissipation device and an upper surface of the second package are at a same level.

7. The semiconductor package of claim 1, wherein an upper surface of the heat dissipation device is higher than an upper surface of the second package.

8. The semiconductor package of claim 1, wherein a cross-sectional area of the heat dissipation device is same as a cross-sectional area of an upper surface of the (1-1)-th semiconductor chip.

9. The semiconductor package of claim 1, wherein a cross-sectional area of the heat dissipation device is different from a cross-sectional area of an upper surface of the (1-1)-th semiconductor chip.

10. The semiconductor package of claim 1, wherein, within the first package, a ratio of a proportion of the first region to a proportion of the second region is set to be 1:1.

11. The semiconductor package of claim 1, wherein, within the first package, the first region is larger than the second region.

12. The semiconductor package of claim 1, wherein the first package further includes a (1-3)-th semiconductor chip mounted to the second region.

13. The semiconductor package of claim 1, further comprising:
a third package comprising at least one semiconductor chip and on an upper side in the second region of the first package.

14. The semiconductor package of claim 1, wherein
the first package includes,
a first redistributed layer (RDL);
a first package substrate on a first surface of the first RDL and configured to accommodate the (1-1)-th semiconductor chip and the (1-2)-th semiconductor chip; and
a first connecting terminal on a second surface of the first RDL, and
the first package substrate includes,
a first pad in the first package substrate and electrically connected to the (1-1)-th semiconductor chip;
a first wiring pattern in the first package substrate and electrically connected to the (1-2)-th semiconductor chip;
a molding configured to surround a periphery of the (1-1)-th semiconductor chip; and
a first insulating layer configured to fill an interior of the first package substrate.

15. The semiconductor package of claim 14, wherein a size of the (1-1)-th semiconductor chip is larger than a size of the (1-2)-th semiconductor chip.

16. The semiconductor package of claim 14, wherein
only a lower surface of the (1-1)-th semiconductor chip is connected to the first pad, and
an upper surface and a lower surface of the (1-2)-th semiconductor chip are connected to the first wiring pattern.

17. A method of manufacturing a semiconductor package, the method comprising:
forming a first package including a (1-1)-th semiconductor chip and a (1-2)-th semiconductor chip;
disposing a heat dissipation device on an upper side in a first region of the first package to which the (1-1)-th semiconductor chip is mounted; and
disposing a second package including at least one semiconductor chip on an upper side in a second region of the first package to which the (1-2)-th semiconductor chip is mounted,
wherein the forming of the first package includes,
embedding the (1-2)-th semiconductor chip in the second region of the first package; and
forming, in the first region of the first package, a cavity that is open toward an upper side of the first package and disposing the (1-1)-th semiconductor chip in the cavity.

18. The method of claim 17, wherein the forming of the first package further comprises:
disposing a first redistributed layer (RDL) on a first surface of the first package; and
disposing a first connecting terminal on a first surface of the first RDL.

19. The method of claim 17, wherein the disposing the heat dissipation device comprises disposing the heat dissipation device such that a lower surface of the heat dissipation device faces an upper surface of the (1-1)-th semiconductor chip.

20. The method of claim 19, wherein the disposing the heat dissipation device further comprises disposing a thermal interface material (TIM) layer between the upper surface of the (1-1)-th semiconductor chip and the lower surface of the heat dissipation device.

21. (canceled)
